(19) United States
(12) Patent Application Publication
(10) Pub. No.: US 2024/0070354 A1
(43) Pub. Date: Feb. 29, 2024

(54) SYSTEM AND METHODS FOR AUDITABLE CORPORATE EMISSION BALANCING

(71) Applicant: SAP SE, Walldorf (DE)

(72) Inventors: Jochen Mayerle, Flein (DE); Astrid Graeber, Walldorf (DE); Veit Spaegele, Wiesloch (DE); Raffael Lutz, Bad Schoenborn (DE)

(21) Appl. No.: 18/078,538

(22) Filed: Dec. 9, 2022

Related U.S. Application Data
(60) Provisional application No. 63/400,118, filed on Aug. 23, 2022.

(51) Int. Cl. G06F 30/28

(52) U.S. Cl. CPC G06F 30/28

(57) ABSTRACT

Mechanisms are disclosed for modelling and quantitatively characterizing emissions inflows and outflows. Scoping inputs are received including a physical process defined scope of emission-producing physical inputs. Modeling inputs are received, including footprints associated with physical manufacturing inputs. The model energy flows may be provided via a graphical modeling user interface and support allocation rule definitions for distributing emissions footprint definitions. An estimated emission flow is calculated based on combined energy flows. The material flows may be derived from aggregated transaction data associated with emission-producing physical inputs. The calculated emission flow may be based on a calculated emission footprint at stages along a production process. Analytics user interfaces associated with the calculated emissions flows may provide insight into the highest emission producing emission drivers along the production chain in connection with a technical report.

### TECHNICAL FIELD

The present application claims the benefit and priority of U.S. Provisional Application No. 63/400,118, filed Aug. 23, 2022, entitled “MODELING EMISSIONS TRACING,” the entire contents of which are incorporated herein by reference in its entirety for all purposes.

Embodiments generally relate to modelling and quantitatively characterizing a complete emission inflow and outflow for a manufacturer over a certain period based on a set of physical transactions.

Managing certain types of emissions associated with manufacturing involves understanding associated anthropogenic Greenhouse Gas (GHG) emissions footprint associated with corresponding plant and equipment associated with production. GHG emissions are typically a result of many distributed technical factors associated with various manufacturing processes. To facilitate reduction of an arbitrary GHG footprint, significant resources and efforts are required to analyze the impact of production, transportation, logistics, and otherwise embedded contribution of procured materials, components, and energy to the overall greenhouse gas balance of services and finished goods. As a result, producing entities may be motivated to be able to disclose certain types of emissions associated with production, fairly and accurately. In order to comply with certain future regulatory requirements, manufacturing entities desire reliable mechanisms to determine and report incoming and outgoing emissions streams in an auditable manner. An associated benefit would be to facilitate reduction of emissions associated with certain industrial processes. Producers with high emissions may find themselves at a strategic competitive disadvantage. Therefore, producers having high levels of emissions may be motivated to gloss over or otherwise hide certain respective emissions. It takes significant resources to identify such producers and to differentiate those producers who provide an accurate characterization of their emissions from those who hide emissions. On the other hand, producers that are able to reduce emissions by way of energy efficiency measures and emission-neutral processes have a natural interest in making their emissions accounts complete and transparent to take credit for their successful reductions of emissions. Consumers of data regarding product carbon footprint have a vested interest in the accuracy and veracity of corresponding received data. Such accuracy and traceability from the point of view of a data recipient plays a crucial role in accurately quantitatively characterizing overall emissions from various entities. Accordingly, producers face increasing external pressure to provide credible data that can be validated and relied upon. To accomplish this, some producers expend significant resources to capture, measure, and validate data associated with emissions, in some cases requiring a team of engineers to closely analyze the operation of a factory, for example. Such problems are relevant not only to GHG emissions: Land use, water use, and other environmental aspects may be addressed in a similar way. Accordingly, what is needed are automated mechanisms for modelling and quantitatively characterizing emissions inflows and outflows for an entity (such as a manufacturer) over a certain period based on a set of physical transactions, thereby addressing the above-mentioned problems and resource constraints.

### SUMMARY

Disclosed embodiments address the above-mentioned problems by providing one or more non-transitory computer-readable media storing computer-executable instructions that, when executed by a processor, perform a method for providing automated mechanisms for modelling and quantitatively characterizing emissions inflows and outflows for an entity over a certain period based on a set of physical transactions, the method comprising: receiving a plurality of scoping inputs including a physical process defined scope of emission-producing physical inputs, the plurality of scoping inputs including: a technical input definition and one or more reliability ratings; receiving a plurality of modeling inputs including one or more associated footprints associated with physical manufacturing inputs, the one or more associated footprints including: user provided footprint inputs, information provided via a data processing integration with one or more suppliers of physical inputs; and inputs derived from one or more lifecycle assessment (LCA) databases, the plurality of modeling inputs further including one or more model energy flows associated with one or more production processes, wherein the model energy flows may be provided via a graphical modeling user interface and one or more support allocation rule definitions for distributing one or more overhead emissions footprint definitions; calculating an estimated emission flow based on one or more combined energy flows, based at least in part on the plurality of modeling inputs and one or more material flows, wherein the one or more material flows us derived from aggregated transaction data associated with the physical process defined scope of emission-producing physical inputs, wherein the calculated emission flow is based on a calculated emission footprint at a plurality of stages along a production process; and providing one or more analytics user interfaces associated with the calculated emissions flows to provide insight into the highest emission producing emission drivers along the production chain and aggregating associated data into a technical report, the technical report being correlated with a balance sheet associated with the manufacturing entity.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present teachings will be apparent from the following detailed description of the embodiments and the accompanying drawing figures.

### BRIEF DESCRIPTION OF THE DRAWING FIGURES

Embodiments are described in detail below with reference to the attached drawing figures, wherein:

FIG. 1 is a system architecture diagram illustrating an example system for providing automated mechanisms for modelling and quantitatively characterizing emissions inflows and outflows for an entity over a certain period based on a set of physical transactions consistent with the present teachings.

FIG. 2 is an example integration design diagram illustrating an example integration for providing automated mechanisms for modelling and quantitatively characterizing emissions inflows and outflows for an entity over a certain period based on a set of physical transactions consistent with the present teachings.

FIG. 3 shows an example data packaging diagram for providing automated mechanisms for modelling and quantitatively characterizing emissions inflows and outflows for an entity over a certain period based on a set of physical transactions consistent with the present teachings.

FIG. 4 is a flow diagram illustrating an example method for providing automated mechanisms for modelling and quantitatively characterizing emissions inflows and outflows for an entity over a certain period based on a set of physical transactions according to certain embodiments.

FIG. 5 is a diagram illustrating a sample computing device architecture for implementing various aspects described herein.

The drawing figures do not limit the present teachings to the specific embodiments disclosed and described herein. The drawings are not necessarily to scale, emphasis instead being placed upon clearly illustrating the principles of the disclosure.

### DETAILED DESCRIPTION

The subject matter of the present disclosure is described in detail below to meet statutory requirements; however, the description itself is not intended to limit the scope of claims. Rather, the claimed subject matter might be embodied in other ways to include different steps or combinations of steps similar to the ones described in this document, in conjunction with other present or future technologies. Minor variations from the description below will be understood by one skilled in the art and are intended to be captured within the scope of the present claims. Terms should not be interpreted as implying any particular ordering of various steps described unless the order of individual steps is explicitly described.

The following detailed description of embodiments references the accompanying drawings that illustrate specific embodiments in which the present teachings can be practiced. The described embodiments are intended to illustrate aspects of the present teachings in sufficient detail to enable those skilled in the art to practice the present teachings. Other embodiments can be utilized, and changes can be made without departing from the claims. The following detailed description is, therefore, not to be taken in a limiting sense. The scope of embodiments is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate reference to “one embodiment” “an embodiment”, or “embodiments” in this description do not necessarily refer to the same embodiment and are also not mutually exclusive unless so stated and/or except as will be readily apparent to those skilled in the art from the description. For example, a feature, structure, or act described in one embodiment may also be included in other embodiments but is not necessarily included. Thus, the technology can include a variety of combinations and/or integrations of the embodiments described herein.

### Overview

The present teachings describe methods and systems to facilitate modelling and quantitatively characterizing complex emission inflows and/or outflows for producing entities over a certain period based on a set of physical transactions. It is understood that producing entities may include any type of entity that may cause emissions, including but not limited to governments, governmental agencies, corporations and other for-profit or not-for-profit entities. In some embodiments, this may be facilitated by processes of emission balancing. In some embodiments, a target audience for associated output reports report may be e.g., an external auditor, chief financial officer (CFO), board of directors, internal audit committee, etc. Such reports may provide, for example, a central report for reporting on emission balancing. Such a report may cover associated emissions corresponding to a defined organizational unit comprising a footprint inventory scope describing a monthly rolling emissions footprint. Such a report may also include a defined time scope, such as footprint inventory for the month of May 2022. On the left side such a report may illustrate an “inflow” corresponding to all incoming emissions. In such an example it may correspond to certain CO2 equivalents, received for a particular organizational unit, from different sources, for a particular time period. Such a report may show on a right side “outflows” corresponding to use of emissions for the particular organizational unit, for the particular time period. Organizational boundaries of such a calculation may be e.g., a physical site or logical organizational division of a manufacturer, a single company, or a group of affiliated sites, divisions, or producers. Lines of the report may break down the inflow by particular GHG protocol categories plus emissions contained in the opening inventory for the period and the outflow by the use of emissions based on the total logistics transactions of an enterprise resource planning (ERP) system used plus ending inventory for the period. Note that the outflow provides a distinction between product inventory and corporate overhead.

Capturing the inflow of emissions is based on ERP data, energy bills, and amendments e.g., for emissions from chemical processes or fugitive emissions. The latter may either be entered manually or imported from dedicated emission management systems. Those data can be verified with low effort, as the corresponding ERP data are already subject to financial audit and energy bills are legally binding documents. Systems consistent with the present teachings provide mechanisms that automatically map an inflow to the periodic output of an enterprise, rendering it quite difficult to omit part of these emissions ostensibly inadvertently on the way to make its products look better than they are. This system is based on four pillars: the system captures on one hand ERP data that track all relevant goods movements, production and service activities, as well as deliveries and material and service consumption. Such systems allow modelling of energy flows to bridge the gap between energy bills and production activities, as energy consumption is typically not captured in ERP systems. The model consisting of external energy sources, meters, process infrastructure, facility and the equipment used for production. The latter allows the system to roll-up energy consumption to production activities and the manufactured products. To ensure that no energy is intentionally or inadvertently omitted on the way, systems consistent with the present teachings enforce that all energy which enters the system is either allocated to machines in the production line or facility (like warehouses, office heating). In some embodiments, the present teachings employ a set of calculation methods which comply with the law of energy preservation, even if metering is imperfect. Additional emissions that are entered manually or imported from emission management systems can be allocated to products or equipment causing corresponding emissions. From there, the system automatically allocates the emission to the consumers of these products or equipment. It also implements checks to report errors in case of missing allocation rules. The specific choice of line items used to report the outflow ensures that the system is complete and that the total inflow will always match the total outflow.

Products actually sold are considered as well as work in process, which are incomplete production processes that did not yet render finished output products. Additionally, material consumption may be mapped according to cost centers and project energy consumption: Also captured is any energy consumption by equipment or a facility that was not allocated to production (e.g., heating for office buildings) as well as an ending inventory of produced goods that have not been sold or delivered. Together, these four elements ensure that inflow and outflow always balance, and from there an auditor can drill-down to trace flows and allocations in detail, via an automatic system that can be trusted without recourse to visiting a factory with a team of engineers. Such reliable automation provides a dramatic improvement over traditional mechanisms that require a site visit by technical experts to investigate the production process and equipment. Significant to the present teachings is the fact that total Inflow equals total outflow. The present teachings ensure this via calculation algorithms and definitions of outflow categories. A user of systems consistent with the present teachings may influence the category, into which an emission flows, but the user cannot hide the emissions entirely. In an example, a user of systems consistent with the present teachings may choose to allocate emissions related to facility to products or not. The first makes sense in case of product-related facility like a warehouse, and the emissions would hence be reported in product related sections like ‘goods issued’ or ‘ending inventory.’ The latter would be appropriate for office buildings, and the related emissions would be reported as corporate overhead in a section entitled “energy consumption.”

Systems consistent with the present teachings may even be implemented in such a way that the company concerned cannot influence the data from the ERP system used in the report. In principle, all transactions that are relevant to emissions are considered. It is not possible to exclude certain transactions, e.g., through customizing. It is only possible to add further manual transactions. However, the system records these manual interventions via a change-log mechanism with corresponding user and access rights. The report is an excellent starting point for an external auditor, as this report provides also drill-down capabilities to the underlying transactions and individual documents. These logging capabilities provide further analysis paths for auditors.

Low emissions for “Sold Goods,” high emissions for row “Energy Consumption” may lead to a conclusion that parts of the emissions were improperly misallocated to the products, which may be visualized in connection with a detailed analysis of a product carbon footprint report. In a case that flow emission source(s) are missing or have only very low emission sources, this implies analysis of each emission source according to the GHG protocol, e.g., control of supplier invoices of electricity and gas suppliers according to the prima nota principle, whereby a source of information designated as a prima nota is designated as a primary source of truth and not be modifiable without generating a permanent audit log entry and the creation of a new and distinct prima nota.

According to an implementation approach having certain key characteristics, a solution consistent with the present teachings may be a cloud-native system built on cloud-based platform as a service solution. At its core, such a solution emphasizes reuse of an architecture blueprint, data models and algorithms from an ERP system having actual product costs. For end-to-end calculation of a value chain from purchasing to sales including actual activity rates at period end, solutions consistent with the present teachings may be delivered with pre-enabled integrations to multiple ERP systems and may be open for connection to other ERP systems as well.

In some embodiments, a unified flow model may be provided. Such a model provides a cohesive and unified flow model to encompass all inflow and outflow of material and intangible goods and services including energy flows and product-related activities and the related emission of the period, door to door of a manufacturer, for example. The unification includes the following sub-networks which are combined by a network calculation algorithm into an overall, cohesive network. Material and process flows from ERP systems provide an energy flow model as well as an associated allocation model. The flow model itself may be implemented in the form of a single-directed multi-graph (or “net”) using underlying technology of associated network calculation algorithms.

In some other embodiments, a complete emission outflow may be provided by way of an algorithmic breakdown of outflow emissions into the business categories established from the balance sheet and profit and loss statement based on goods issued to customers, work in progress, closing inventory, internal consumption of materials, and internal consumption of energy. Through such an algorithmic subdivision, not only the more easily identifiable emissions for the production and sale of products and services can be considered, but actually all emissions outflows according to their underlying category by way of the underlying technology of emission balancing algorithms.

In some other embodiments, auditability through already audited or easy to audit source documents may be provided. The basis for the unified flow model may be formed by elementary data available from any ERP system, which is also used in such an ERP system, among other things, for the creation of the balance sheet and profit and loss statement. From the point of view of an emissions auditor, this data set can be considered as already audited data. For the emissions inflow, e.g., from purchased energies (GHG category 2), direct emissions from burned oil or gas (GHG category 1) can be proven to an emission auditor via a so-called prima nota which is considered a first and original entry document as well as other documents, such as an invoice document from a service provider.

As a result, the emissions reporting that can be easily audited by an accountant rather than an engineering team. Underlying technology: API-level definitions for ERP-agnostic integration as documented in connection with an API Hub (such as the SAP API Hub). Systems consistent with the present teachings provide a definition of a simple and universal set of business transactions with a minimal set of attributes that can be found in any ERP system which allows the creation of the complete gate-to-gate model for inflow-outflow tracking of emissions as described above. This API also allows optional tracking of transport-related emissions (up-stream, down-stream and internal). For this, it may be important to capture a multitude of types of returns explicitly. Quantities given in a corresponding list may be made up of a tuple of a numeric value and a corresponding unit of measure. Transport routes may be optional and consist of ship-from location; ship-to-location; list of distances and associated means of transport. This may include the following structure:

Opening Inventory Material Identifier Inflow
Plant Identifier
Quantity

Goods Receipt without Reference Material Identifier Inflow
Plant Identifier
Quantity

Goods Receipt from Supplier

Return to Supplier Material Identifier Inflow
Plant Identifier
Supplier Identifier
Transport Route
Quantity

Goods Issue for Production Material Identifier
Plant Identifier
Production Document Identifier
Quantity

Internal Service Confirmation Resource Identifier Equipment that was Used, e.g., Oven
Service Identifier Service provided by the equipment, e.g., baking at 180° C.
Production Document Identifier
Plant identifier
Service quantity
Resource quantity

Goods Receipt from Production Material Identifier
Plant Identifier
Production Document Identifier
Material role code Main product, by-product, joint product
Quantity

Goods transfer including source material identifier may either represent a transfer of a material from one plant to another plant, or in an exceptional case that a material identifier changes, e.g., because a goods receipt was improperly labeled. In some embodiments, a bottom-up matching inflow with outflow may be provided. This may employ an algorithm that puts the unified flow model into a matching structure, similar to a double-entry bookkeeping in an accounting system. For this purpose, the inflow page, which is already structured according to emissions may be brought into a matching structure with the complete outflow as described above, which is structured according to business management requirements. The underlying data selection that ensures that all inflow of the system is tracked and mapped to one of the outflow categories. Underlying technology, ay involve emission balancing algorithms.

### Operational Environment for Embodiments

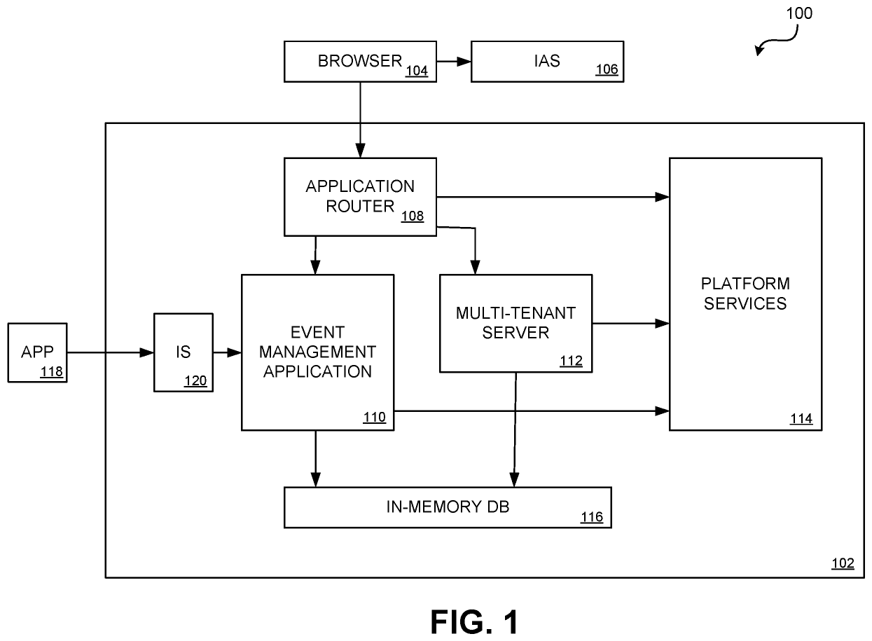

FIG. 1 is a system architecture diagram 100 illustrating an example system for providing automated mechanisms for modelling and quantitatively characterizing emissions inflows and outflows for an entity over a certain period based on a set of physical transactions. Replication activities and calculation runs may put heavy loads on various systems within architecture diagram 100 but occur mostly during an end of cycle, e.g., end of month. On the other hand, ongoing user interaction activities may be triggered frequently while nevertheless placing a relatively low load on associated component systems. As a result, there may be benefits associated with utilizing computational resources efficiently, reserving high compute power for times of heavy computational load, scaling down once heavy load computations are completed. In some embodiments, a multi-threaded behavior is provided to utilize the processing power of the cloud platform (e.g., by using Worker Threads). Accordingly, based on particular workload elasticity and usage-based pricing for high-cost services such as in-memory database system 116, elastic cloud implementations may be beneficial in managing total cost of ownership.

In some embodiments, using Node.js as a runtime in connection with event management application 110 may be beneficial. In some such embodiments, execution of application code Node.js may be implemented as a single threaded runtime. In some other embodiments, a cross-platform synchronous input/output library such as libuv may be employed, for example when performing OS-related operations, with another option being usage of Worker Threads. Worker Threads may not share context so that a cloud application programming model (CAP) runtime and metadata potentially need to be spawned up in each thread causing a high memory and processing footprint. In scenarios with a large number of requests with a small processing footprint (e.g., the application router scenario depicted in FIG. 1′), this concept may be beneficial. As product footprint management (PFM) systems consistent with the present teachings may involve calculation-intense aspects, architectural choices may have a significant impact on computing resource intensity.

Code that is executed by the Node.js runtime can be provided as JavaScript or Typescript sources. Executing Typescript may require an on-the-fly transcompilation so that within a production environment JavaScript sources are preferably provided. In some embodiments, PFM for clean operations may use Typescript as development language to ensure a reliable definition of used interfaces. In-memory database system 116 may provide a feature-rich database system that is highly optimized for support of OLTP scenarios. As a column store database, the specification of required columns may take on an important role as a SELECT * query requires the decompression of all existing columns. A variety of functions can be accessed using stored procedures and certain benefits may exist to push down significant portions of calculation logic to the database level. However, as database processing may not be scaled horizontally so that dynamic scaling needs to be done on the application level and an overload of the database should be avoided.

PFM for clean operations may be built based on cloud platforms such as Cloud Foundry, however such systems may also be provided in connection with containerized application deployment systems such as Kubernetes. PFM for clean operations may be a cloud-only solution running on existing vendor application platforms such as SAP Business Technology Platform (BTP). In these embodiments, a central service (PFM Application) provides a preponderance of core capabilities. Services associated with event management application 110 may be developed based on CAP using Node.js. The database entities as well as the service definitions may be modeled via SAP Core Data Services (CDS) however any other modeling may be employed without departing from the present teachings. Associated functionality may be implemented using Typescript code to facilitate development and support future code refactoring. A calculation engine associated with event management application 110 may be built as a general-purpose network calculation engine consuming and orchestrating application-specific calculation steps.

For failover scenarios, each Java service application may be started with three instances and at least approximately 4 GB of memory. A preferred option involves using Cloud Foundry tasks, representing a scale to zero option on Cloud Foundry providing the advantage to keep constant memory allocation of services to a minimum. Multi-Tenancy in the Application is enabled using schema separation on database level. A schema may be selected based on the tenant information that is provided via the Java Web Token (JWT) that is used for authentication and authorization services. To handle tenant schema onboarding actions and tenant schema upgrades a PFM application may be deployed twice, with a second instance being invoked via application router 108 in case a software-as-a-system registry calls onboarding APIs or directly out of the pipeline via a technical user to perform a tenant upgrade, for example. As the module that is used to calculate the database schema information to deploy it via the in-memory database system 116 deployment infrastructure performs calculation intense operations CAP may operate in connection with the deployment as a dedicated application. To implement multi-tenant functionality, application router 108 may also connect to multi-tenant server 112 which itself is connected to in-memory database system 116 and platform services 114.

In some embodiments, users access PFM application 102 via application router 108 using browser 104 after being authenticated via identity authentication service (IAS) 106. In these embodiments, application router 108 may provide a security assertion markup language (SAML 2.0) authorization flow together with IAS 106, requesting a JSON web token (JWT) token from a central infrastructure component if no valid user session can be determined. Various implementations of application router 108 may be enhanced to handle tenant onboarding calls and forward them to various connected services and applications. Application router 108 may be connected to platform services 114 that implement a plurality of services, including application logging, audit logging, and portal services as well as application registry functions. In connection with platform services 114, a logging deployer may deploy internationalized logging templates that may be used to create end-user ready logs during calculations. As debugging options may not be conveniently available in connection with certain cloud platforms, technical application logs may be verbose and contain significant quantities of technical information that should not be provided to end-users for security purposes. Accordingly, separate logging services may be used to store logs that are written during the execution of the calculation batch job for provision to end users.

Data may be replicated to PFM application 102 for performance reasons. For the purpose of replication integration flows may be provided in a subscribed ERP suite application. User interfaces associated with PFM application 102 may be based on a user interface framework such as SAP Fiori Elements consuming data via ODataV4, however it is understood that any user interface framework may be employed without departing from the scope of the present teachings. Custom user interface controls may be implemented using React and may be embedded into the Fiori Elements user interface components. Resources may be served using an HTML5 apps repository. A Sankey chart is a type of flow diagram in which the width of the arrows is proportional to the flow rate. Sankey diagrams can also visualize energy quantities, material flow quantities, broken down by category, and/or cost breakdowns. Such diagrams may be used in the visualization of material flow analysis and are therefore appropriate for visualizing emissions. In another use case, a stand-alone application such as cloud-based ERP application 118 may be integrated into PFM application 102 by way of a dedicated integration suite such as integration suite 120, which provides an interface to PFM application 102 by way of a connection to event management application 110.

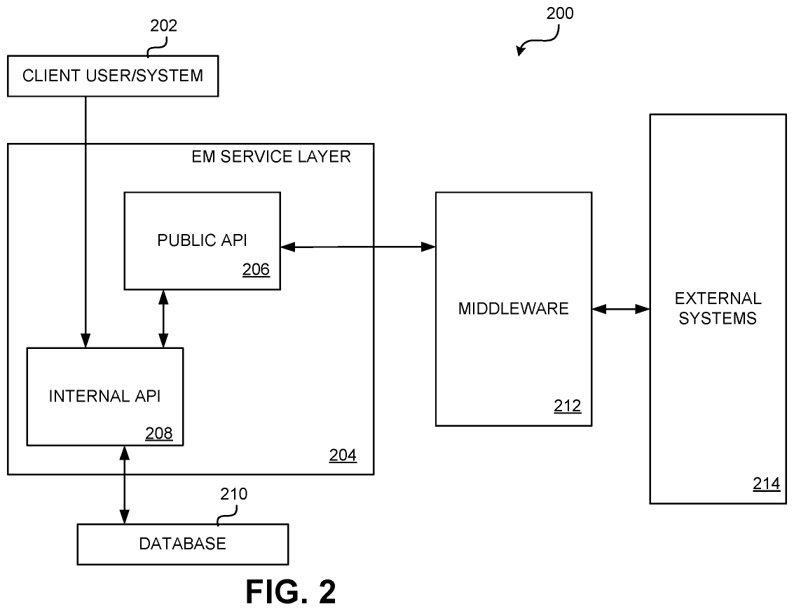

FIG. 2 is an example integration design diagram 200 illustrating an example integration for providing automated mechanisms for modelling and quantitatively characterizing emissions inflows and outflows for an entity over a certain period based on a set of physical transactions. Client user and/or system 202 may be any number of client systems such as standalone on-premises or cloud-based ERP systems or other web-based applications. Client user and/or system 202 may connect directly to event management service layer 204 by way of internal API 208. Internal API 208 is itself connected to database 210, which may be an in-memory database. Internal API 208 may connect to middleware system 212, which itself mediates connections to an arbitrary number of external systems 214. Middleware 212 may also provide access to event management service layer 204 via public API 206, which itself may access content contained within database 210 by way of internal API 208. A further connection (not shown) may implement database connectivity directly between public API 208 and database 210.

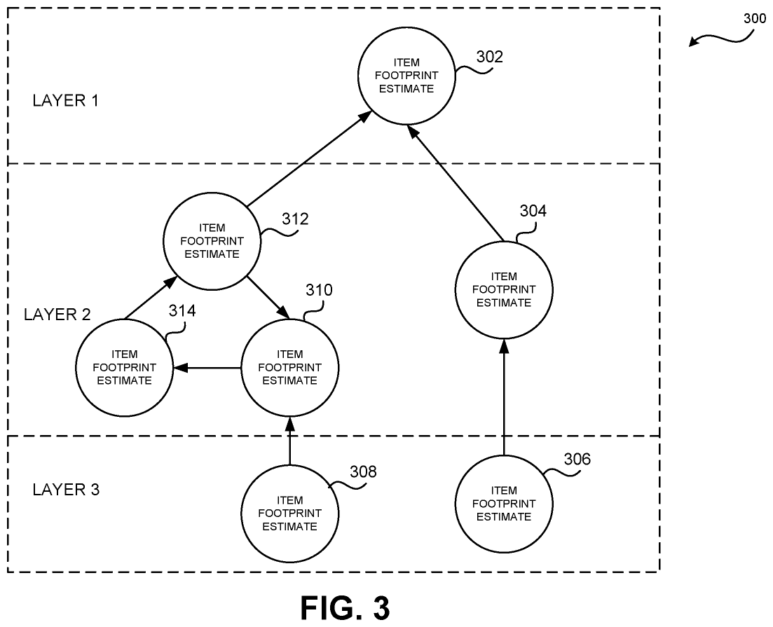

FIG. 3 shows an example data packaging diagram 300 for providing automated mechanisms for modelling and quantitatively characterizing emissions inflows and outflows for an entity over a certain period based on a set of physical transactions consistent with the present teachings. Steps corresponding to a data creation phase may generate footprint data based on an energy flow model and replicated transaction data. Footprint input items typically reference at least one item footprint estimate root node, such as node 302. As it cannot be known in advance whether a referenced root node has already been created, an identifier associated with a referenced entity may not be initially populated. A data post creation phase is triggered when a complete set of item footprint estimates has been created. After creation of item footprint estimates, it becomes possible to link complete set of item footprint estimates. This might also lead to the occurrence of cycles that are to be treated specially. Cycles may be represented as shown in FIG. 3 where node 308 references node 310 which itself references node 314 which indirectly connects back to node 310 via node 312. A non-cyclical path through layers 1 through 3 passes from node 308 in layer 3 to node 304 in layer 2 and finally to node 302 in layer 1. Furthermore, in this phase the footprint of purchased products may be determined in a second step and a third steps populates the description from referenced master data entities to the referencing item footprint estimates.

A data layering step consistent with the present teachings may leverage an in-memory database system by incorporating in-memory database graph technology to determine the layers of and cycles in the network of item footprint estimates. In-memory database system graphs may be used within a stored procedure. Within the timeframe of this step the whole network needs to be kept in the main memory of the database. Subsequent steps provide the opportunity to split the data. A subsequent step of data packaging may then be performed. This step is used to derive packages of nodes within a layer. The nodes may be packaged by: layer, cycles, and item type (due to a possibility of mass data handling within a particular calculation as such a calculation may be item type based). There are several reasons for the packaging step. Each node on a particular level can be calculated at the same time however cycles need to be calculated in various iterations with a defined stop condition and entities with the same type can be handled in bulk. Furthermore, splitting the data into small packages reduce an overall amount of consumed memory.

After data preparation has been finalized, a final calculation may be triggered. An entire network of item footprint estimates may be processed first in a top-down order and in a second iteration in a bottom-up order. The actions performed in the executed calculation steps differ depending on execution order. For top-down, each Top-Down step will receive item footprint estimate root nodes of one level and item type together with its output and input edges. The output edges may be considered to calculate the required values on the root node and the root nodes may be used to calculate the values on the input edges. The output edges may remain untouched. This step calculates, for example, the output quantity on the nodes as a sum of the quantities on the output edges. Bottom-up calculation is the final calculation step. It will roll up an overall emissions quantity from leaf nodes through the network to the output materials. The final results may be visualized in connection with a Sankey chart that maps input sources to outputs.

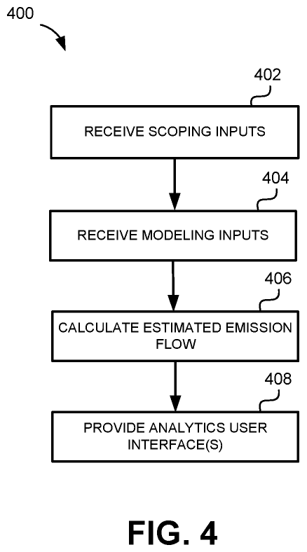

FIG. 4 is a flow diagram 400 illustrating an example method for providing automated mechanisms for modelling and quantitatively characterizing emissions inflows and outflows for an entity over a certain period based on a set of physical transactions according to certain embodiments. At step 402, a plurality of scoping inputs is received, including a physical process defined scope of emission-producing physical inputs, the plurality of scoping inputs including: a technical input definition and one or more reliability ratings. At step 404, a plurality of modeling inputs is received including one or more associated footprints associated with physical manufacturing inputs, the one or more associated footprints including: user provided footprint inputs, information provided via a data processing integration with one or more suppliers of physical inputs; and inputs derived from one or more lifecycle assessment (LCA) databases, the plurality of modeling inputs further including one or more model energy flows associated with one or more production processes.

At step 406, an estimated emission flow is calculated based on one or more combined energy flows, based at least in part on the plurality of modeling inputs and one or more material flows. At step 408, one or more analytics user interfaces associated with the calculated emissions flows is provided to provide insight into the highest emission producing emission drivers along the production chain and aggregating associated data into a technical report, the technical report being correlated with a balance sheet associated with the manufacturing entity.

In some embodiments, the model energy flows are provided via a graphical modeling user interface and one or more support allocation rule definitions for distributing one or more overhead emissions footprint definitions. In these embodiments, the one or more material flows us derived from aggregated transaction data associated with the physical process defined scope of emission-producing physical inputs. The calculated emission flow is based on a calculated emission footprint at a plurality of stages along a production process. In some embodiments, the calculated emission flow may be visualized in connection with a Sankey chart. Providing one or more analytics user interfaces may include providing an emissions report mapping emissions to entries in an accounting system. In some embodiments, the emissions outflows correspond to a quantity of carbon emissions.

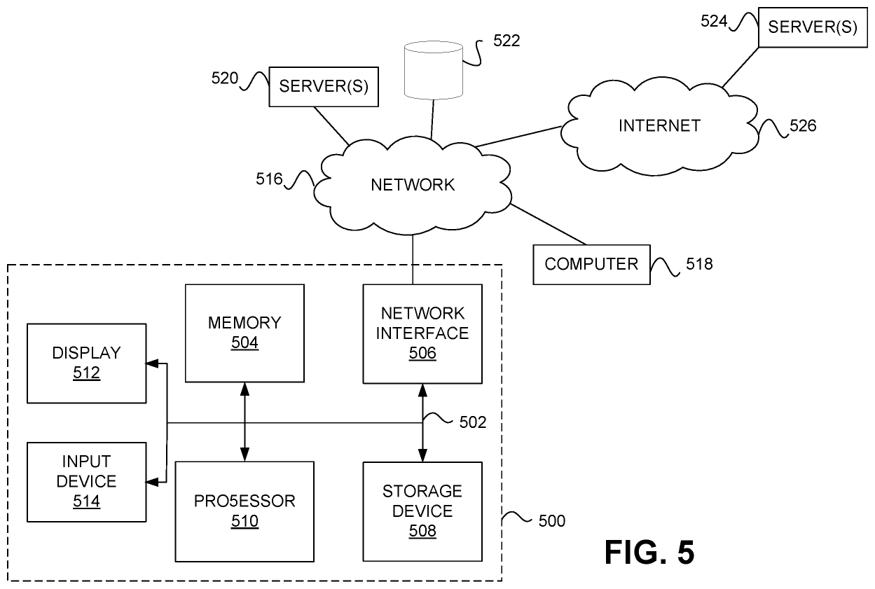

FIG. 5 is a diagram illustrating a sample computing device architecture for implementing various aspects described herein. Computer 500 can be a desktop computer, a laptop computer, a server computer, a mobile device such as a smartphone or tablet, or any other form factor of general- or special-purpose computing device containing at least one processor that may be employed to cause actions to be carried out. Depicted with computer 500 are several components, for illustrative purposes. Certain components may be arranged differently or be absent. Additional components may also be present. Included in computer 500 is system bus 502, via which other components of computer 500 can communicate with each other. In certain embodiments, there may be multiple busses or components may communicate with each other directly. Connected to system bus 502 is processor 510. Also attached to system bus 502 is memory 504. Also attached to system bus 502 is display 512. In some embodiments, a graphics card providing an input to display 512 may not be a physically separate card, but rather may be integrated into a motherboard or processor 510. The graphics card may have a separate graphics-processing unit (GPU), which can be used for graphics processing or for general purpose computing (GPGPU). The graphics card may contain GPU memory. In some embodiments no display is present, while in others it is integrated into computer 500. Similarly, peripherals such as input device 514 is connected to system bus 502. Like display 512, these peripherals may be integrated into computer 500 or absent. Also connected to system bus 502 is storage device 508, which may be any form of computer-readable media, such as non-transitory computer readable media, and may be internally installed in computer 500 or externally and removably attached.

Computer-readable media include both volatile and nonvolatile media, removable and nonremovable media, and contemplate media readable by a database. For example, computer-readable media include (but are not limited to) RAM, ROM, EEPROM, flash memory or other memory technology, CD-ROM, digital versatile discs (DVD), holographic media or other optical disc storage, magnetic cassettes, magnetic tape, magnetic disk storage, and other magnetic storage devices. These technologies can store data temporarily or permanently. However, unless explicitly specified otherwise, the term “computer-readable media” should not be construed to include physical, but transitory, forms of signal transmission such as radio broadcasts, electrical signals through a wire, or light pulses through a fiber-optic cable. Examples of stored information include computer-useable instructions, data structures, program modules, and other data representations.

Finally, network interface 506 is also attached to system bus 502 and allows computer 500 to communicate over a network such as network 516. Network interface 506 can be any form of network interface known in the art, such as Ethernet, ATM, fiber, Bluetooth, or Wi-Fi (i.e., the Institute of Electrical and Electronics Engineers (IEEE) 802.11 family of standards). Network interface 506 connects computer 500 to network 516, which may also include one or more other computers, such as computer 518, server(s) 520, and network storage, such as cloud network storage 522. Network 516 is in turn connected to public Internet 526, which connects many networks globally. In some embodiments, computer 500 can itself be directly connected to public Internet 526 as well as one or more server(s) 524.

One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system can include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “computer-readable medium” refers to any computer program product, apparatus and/or device, such as for example magnetic discs, optical disks, memory, and Programmable Logic Devices (PLDs), used to provide machine instructions and/or data to a programmable processor, including a computer-readable medium that receives machine instructions as a computer-readable signal. The term “computer-readable signal” refers to any signal used to provide machine instructions and/or data to a programmable processor. The computer-readable medium can store such machine instructions non-transitorily, such as for example as would a non-transient solid-state memory or a magnetic hard drive or any equivalent storage medium. The computer-readable medium can alternatively or additionally store such machine instructions in a transient manner, for example as would a processor cache or other random-access memory associated with one or more physical processor cores.

Many different arrangements of the various components depicted, as well as components not shown, are possible without departing from the scope of the claims below. Embodiments of the invention have been described with the intent to be illustrative rather than restrictive. Alternative embodiments will become apparent to readers of this disclosure after and because of reading it. Alternative means of implementing the aforementioned can be completed without departing from the scope of the claims below. Certain features and sub-combinations are of utility and may be employed without reference to other features and sub-combinations and are contemplated within the scope of the claims. Although the invention has been described with reference to the embodiments illustrated in the attached drawing figures, it is noted that equivalents may be employed, and substitutions made herein without departing from the scope of the invention as recited in the claims. The subject matter of the present disclosure is described in detail below to meet statutory requirements; however, the description itself is not intended to limit the scope of claims. Rather, the claimed subject matter might be embodied in other ways to include different steps or combinations of steps similar to the ones described in this document, in conjunction with other present or future technologies. Minor variations from the description below will be understood by one skilled in the art and are intended to be captured within the scope of the present claims. Terms should not be interpreted as implying any particular ordering of various steps described unless the order of individual steps is explicitly described.

The following detailed description of embodiments references the accompanying drawings that illustrate specific embodiments in which the present teachings can be practiced. The described embodiments are intended to illustrate aspects of the disclosed invention in sufficient detail to enable those skilled in the art to practice the invention. Other embodiments can be utilized, and changes can be made without departing from the claimed scope of the invention. The following detailed description is, therefore, not to be taken in a limiting sense. The scope of embodiments is defined only by the appended claims, along with the full scope of equivalents to which such claims are entitled.

Having thus described various embodiments of the invention, what is claimed as new and desired to be protected by Letters Patent includes the following:

1. One or more non-transitory computer-readable media storing computer-executable instructions that, when executed by a processor, perform a method for providing automated mechanisms for modelling and quantitatively characterizing emissions inflows and outflows for an entity over a certain period based on a set of physical transactions, the method comprising:
receiving a plurality of scoping inputs including a physical process defined scope of emission-producing physical inputs, the plurality of scoping inputs including: a technical input definition and one or more reliability ratings;
receiving a plurality of modeling inputs including one or more associated footprints associated with physical manufacturing inputs, the one or more associated footprints including: user provided footprint inputs, information provided via a data processing integration with one or more suppliers of physical inputs; and inputs derived from one or more lifecycle assessment (LCA) databases, the plurality of modeling inputs further including one or more model energy flows associated with one or more production processes;
calculating an estimated emission flow based on one or more combined energy flows, based at least in part on the plurality of modeling inputs and one or more material flows; and
providing one or more analytics user interfaces associated with the calculated emissions flows to provide insight into highest emission producing emission drivers along a production chain and aggregating associated data into a technical report, the technical report being correlated with a balance sheet associated with the manufacturing entity.

2. The non-transitory computer-readable media of claim 1, wherein the model energy flows are provided via a graphical modeling user interface and one or more support allocation rule definitions for distributing one or more overhead emissions footprint definitions.

3. The non-transitory computer-readable media of claim 1, wherein the one or more material flows us derived from aggregated transaction data associated with the physical process defined scope of emission-producing physical inputs.

4. The non-transitory computer-readable media of claim 3, wherein the calculated emission flow is based on a calculated emission footprint at a plurality of stages along a production process.

5. The non-transitory computer-readable media of claim 4, wherein the calculated emission flow may be visualized in connection with a Sankey chart.

6. The non-transitory computer-readable media of claim 1, wherein providing one or more analytics user interfaces comprises providing an emissions report mapping emissions to entries in an accounting system.

7. The non-transitory computer-readable media of claim 1, wherein the emissions outflows correspond to a quantity of carbon emissions.

8. A method for providing automated mechanisms for modelling and quantitatively characterizing emissions inflows and outflows for an entity over a certain period based on a set of physical transactions, the method comprising:
receiving a plurality of scoping inputs including a physical process defined scope of emission-producing physical inputs, the plurality of scoping inputs including: a technical input definition and one or more reliability ratings;
receiving a plurality of modeling inputs including one or more associated footprints associated with physical manufacturing inputs, the one or more associated footprints including: user provided footprint inputs, information provided via a data processing integration with one or more suppliers of physical inputs; and inputs derived from one or more lifecycle assessment (LCA) databases, the plurality of modeling inputs further including one or more model energy flows associated with one or more production processes;
calculating an estimated emission flow based on one or more combined energy flows, based at least in part on the plurality of modeling inputs and one or more material flows; and
providing one or more analytics user interfaces associated with the calculated emissions flows to provide insight into highest emission producing emission drivers along a production chain and aggregating associated data into a technical report, the technical report being correlated with a balance sheet associated with the manufacturing entity.

9. The method of claim 8, wherein the model energy flows are provided via a graphical modeling user interface and one or more support allocation rule definitions for distributing one or more overhead emissions footprint definitions.

10. The method of claim 9, wherein the one or more material flows us derived from aggregated transaction data associated with the physical process defined scope of emission-producing physical inputs.

11. The method of claim 10, wherein the calculated emission flow is based on a calculated emission footprint at a plurality of stages along a production process.

12. The method of claim 11, wherein the calculated emission flow may be visualized in connection with a Sankey chart.

13. The method of claim 10, wherein providing one or more analytics user interfaces comprises providing an emissions report mapping emissions to entries in an accounting system.

14. The method of claim 8, wherein the emissions outflows correspond to a quantity of carbon emissions.

15. A system for providing automated mechanisms for modelling and quantitatively characterizing emissions inflows and outflows for an entity over a certain period based on a set of physical transactions, the system comprising:
at least one processor;
and at least one non-transitory memory storing computer executable instructions that when executed by the at least one processor cause the system to carry out actions comprising:
receiving a plurality of scoping inputs including a physical process defined scope of emission-producing physical inputs, the plurality of scoping inputs including: a technical input definition and one or more reliability ratings;
receiving a plurality of modeling inputs including one or more associated footprints associated with physical manufacturing inputs, the one or more associated footprints including: user provided footprint inputs, information provided via a data processing integration with one or more suppliers of physical inputs;
and inputs derived from one or more lifecycle assessment (LCA) databases, the plurality of modeling inputs further including one or more model energy flows associated with one or more production processes;
calculating an estimated emission flow based on one or more combined energy flows, based at least in part on the plurality of modeling inputs and one or more material flows; and
providing one or more analytics user interfaces associated with the calculated emissions flows to provide insight into highest emission producing emission drivers along a production chain and aggregating associated data into a technical report, the technical report being correlated with a balance sheet associated with the manufacturing entity.

16. The system of claim 15, wherein the model energy flows are provided via a graphical modeling user interface and one or more support allocation rule definitions for distributing one or more overhead emissions footprint definitions.

17. The system of claim 15, wherein the one or more material flows us derived from aggregated transaction data associated with the physical process defined scope of emission-producing physical inputs.

18. The system of claim 17, wherein the calculated emission flow is based on a calculated emission footprint at a plurality of stages along a production process.

19. The system of claim 18, wherein the calculated emission flow may be visualized in connection with a Sankey chart.

20. The system of claim 15, wherein providing one or more analytics user interfaces comprises providing an emissions report mapping emissions to entries in an accounting system.
